(19) United States
(12) Patent Application Publication
(10) Pub. No.: US 2019/0146039 A1
(43) Pub. Date: May 16, 2019

(54) Method for Determining the Internal Resistance of Battery Cells, Battery Module, and Device

(71) Applicant: Bayerische Motoren Werke Aktiengesellschaft, Muenchen (DE)

(72) Inventor: Jan Philipp SCHMIDT, Muenchen (DE)

(21) Appl. No.: 16/245,525

(22) Filed: Jan. 11, 2019

Related U.S. Application Data
(63) Continuation of application No. PCT/EP2017/060080, filed on Apr. 27, 2017.

(30) Foreign Application Priority Data
Jul. 12, 2016 (DE) 10 2016 212 633.4

(51) Int. Cl. G01R 31/389; H01M 10/48; G01R 31/3842; G01R 1/20

(52) U.S. Cl. CPC G01R 31/389; H01M 10/482; G01R 31/396; G01R 1/203; G01R 31/3842

(57) ABSTRACT

A method determines the internal resistance of battery cells of a battery module, wherein for this purpose a cell voltage of a battery cell is determined as a voltage of the respective electrochemical unit of the battery cell, a cell current of a battery cell is determined from a voltage drop on a cell measuring resistor of the battery cell, and the ohmic resistance of a component of the battery cell in the conductive path is used as a cell measuring resistor.

### CROSS REFERENCE TO RELATED APPLICATIONS

This application is a continuation of PCT International Application No. PCT/EP2017/060080, filed Apr. 27, 2017, which claims priority under 35 U.S.C. § 119 from German Patent Application No. 10 2016 212 633.4, filed Jul. 12, 2016, the entire disclosures of which are herein expressly incorporated by reference.

### BACKGROUND AND SUMMARY OF THE INVENTION

The present invention relates to a method for determining the internal resistance of battery cells, to a battery module and to a device. The present invention relates in particular to a method for determining the internal resistance of battery cells of a battery module, to a battery module for a device, a vehicle or the like, and to a vehicle.

For the energy supply of operating devices in general, of vehicles, for example motor vehicles, hybrid vehicles and the like, battery modules consisting of a plurality of battery cells are increasingly being used. In order to be able to plan and evaluate the operation of such devices and in particular of the battery modules used therein, it is often essential to determine the internal resistance of the individual battery cells of a module.

Disadvantages in the case of conventional operating methods and battery modules are the temporal gap between a voltage measurement in the individual battery cells and the required current measurement and the necessary complexity of the apparatus used to reduce this temporal gap.

The invention is based on the object of providing a method for determining the internal resistance of battery cells, a battery module and a device, in all of which it is possible to accurately determine the internal resistance of individual battery cells of an underlying battery module using particularly simple means.

This and other objects are achieved by a method for determining the internal resistance of battery cells, by a battery module, and by a device, in accordance with embodiments of the invention.

According to a first aspect of the present invention, a method for determining the internal resistance of battery cells of a battery module is provided, wherein, for this purpose, (i) a cell voltage of a battery cell is determined as a voltage of the respective electrochemical unit of the battery cell, (ii) a cell current of a battery cell is determined from a voltage drop across a cell measurement resistor of the battery cell, and (iii) the ohmic resistance of an internal cell component of the battery cell is used in the conductive path as a cell measurement resistor. The conductive path is also called a string of battery cells and of the underlying battery module.

By using an internal cell component as a cell measurement resistor, the need to modify a battery cell to be measured is eliminated. In particular, the need to provide an additional measurement resistor, in particular a precision measurement resistor, is eliminated.

The electrical internal resistance R_{cell} of the cell may be determined from the measured values—that is to say from the measured electric cell voltage U_{cell} and from the measured electric cell current I_{cell} through division in accordance with relationship (1)

R_{cell}=U_{cell}/I_{cell} (1)

at a given time or in a time interval with constant conditions.

In principle, all of the components of the battery cell are available as components for use as a cell measurement resistor, provided that they are present in the conductive path of the battery cell and transfer the flow of current externally.

In one preferred refinement of the method according to the invention, a cell terminal, a feed line or outlet line to or from a cell terminal, and/or a cell connector for connecting adjacent battery cells in a battery module, are used as components in the conductive path of the battery cell.

Since, during operation of an underlying battery module, the cell voltage and the cell current of a respective battery cell of the battery module may be subject to temporal fluctuations, according to another development of the method according to the invention, it is particularly advantageous for the cell voltage U_{cell} and the cell current I_{cell} of a respective battery cell to be measured within a latency time interval of 10 μs.

The cell voltage U_{cell} and the cell current I_{cell} of a respective battery cell are preferably measured at the same time.

The components of a respective battery cell, which components are able to be used as a basis for a cell measurement resistor, are often not designed in a standardized manner as internal structures and/or are subject to temporal changes. In order nevertheless to be able to accurately determine the cell resistance of a respective battery cell, according to one advantageous refinement of the method according to the invention, it is provided that the cell measurement resistor of a respective battery cell is calibrated using a precision measurement resistor external to the cell, in particular through a comparative measurement of a flow of electric current.

The calibration may be performed once or several times, possibly also regularly, for example during a charging procedure.

Temperature compensation is also possible with the calibration.

Advantageously, the cell measurement resistors of the respective battery cells are calibrated using the same precision measurement resistor that is external to the cell with respect to all battery cells. In this way, all of the internal resistances of the individual battery cells that are to be determined refer to the same reference value.

The calibration then proves to be particularly conclusive if, according to another refinement of the method according to the invention, a cell measurement resistor of a respective battery cell is calibrated during a time interval with a constant flow of current, which is in particular at least 10 ms.

There are various procedures for determining a situation with a constant flow of current for calibrating the cell measurement resistors.

According to a first alternative, the constant flow of current for calibrating cell measurement resistors is set by explicitly choosing operating conditions of a battery module underlying the battery cells.

As an alternative or in addition, it may be provided that, during operation in which the flow of current is monitored in any case, a time interval with a constant flow of current is determined afterwards and used as a basis for the calibration.

A particularly flexible refinement of the method according to the invention is then achieved when a current measurement value of a respective battery cell, acquired from comparative measurement of a flow of electric current for calibration purposes, is communicated, in particular to all battery cells of an underlying battery module and/or to a cell monitoring device formed in a respective battery cell.

In another refinement of the method according to the invention, the temporal changes in the properties of the individual battery cells may be taken into account in that a result of the calibration of a cell measurement resistor is stored and/or updated in a lookup table, in particular in the respective battery cell and/or in a cell monitoring device formed in a respective battery cell.

According to another aspect of the present invention, a battery module for a device and, in particular, for a vehicle is provided, which battery module is designed with a plurality of battery cells. The battery cells are connected to one another via a conductive path.

According to the invention, the battery module is designed to be used in the method according to the invention.

To this end, the battery module according to the invention in particular has a monitoring device, a precision resistor external to the cell in the conductive path and/or a cell monitoring device in each of the battery cells.

According to another aspect of the present invention, a device using the battery module according to the invention is provided. This device may, in particular, be a vehicle, for example a motor vehicle, a hybrid vehicle or the like.

The proposed device is designed with a battery module according to the invention and has a load that is able to be connected or is connected to the battery module in order to be supplied with energy.

The load may be a motor for propelling a vehicle, any other motor or any other unit.

Other objects, advantages and novel features of the present invention will become apparent from the following detailed description of one or more preferred embodiments when considered in conjunction with the accompanying drawings.

### BRIEF DESCRIPTION OF THE DRAWINGS

FIG. 1 is a schematic block diagram of one embodiment of the energy module according to the invention.

FIG. 2 is a schematic block diagram of one embodiment of a battery cell that is able to be used in one embodiment of the battery module according to the invention.

FIG. 3 is a flow diagram that shows one embodiment of a calibration method.

### DETAILED DESCRIPTION OF THE DRAWINGS

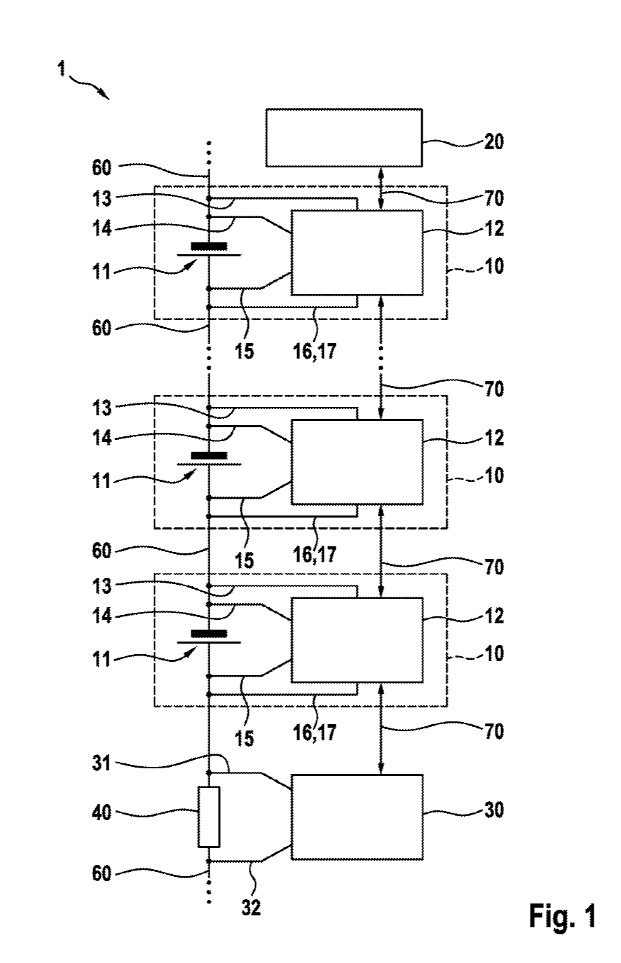

Exemplary embodiments of the invention are described in detail below with reference to FIGS. 1 to 3. Identical and equivalent elements and components or elements and components that act identically or equivalently are referred to using the same reference signs. The detailed description of the referenced elements and components is not repeated each time they occur.

The illustrated features and further properties may be combined as desired separately from one another and with one another as desired without departing from the concept of the invention.

FIG. 1 is a schematic block diagram that shows one embodiment of a battery module 1 according to the invention using a plurality of battery cells 10.

The battery cells 10, in the embodiment illustrated in FIG. 1, are connected in series with one another via a conductive path 60, which is also called a string. The outermost ends of the string 60 are adjoined by module connections, these not being illustrated in FIG. 1.

A precision measurement resistor 40 is connected upstream of the plurality of battery cells 10 in the string 60, this precision measurement resistor being tapped off by way of a current monitoring device 30 using measurement lines 31 and 32 connected in parallel for a precise current measurement with regard to the voltage drop occurring there.

In the embodiment according to FIG. 1, the individual battery cells 10 are connected to one another in terms of communication via a bus 70 or a daisy chain 70. The current monitoring device 30 and, in addition, a superordinate monitoring device 20 are also connected to the bus 70.

In the embodiment according to FIG. 1, each individual battery cell 10 of the battery module 1 is configured with an actual electrochemical unit 11 in a series circuit in the string 60 and connected in parallel with a cell monitoring device 12. The cell monitoring device 12 is able to access operating parameters of the electrochemical unit 11 and of the conductive path 60 via measurement lines 13 to 17.

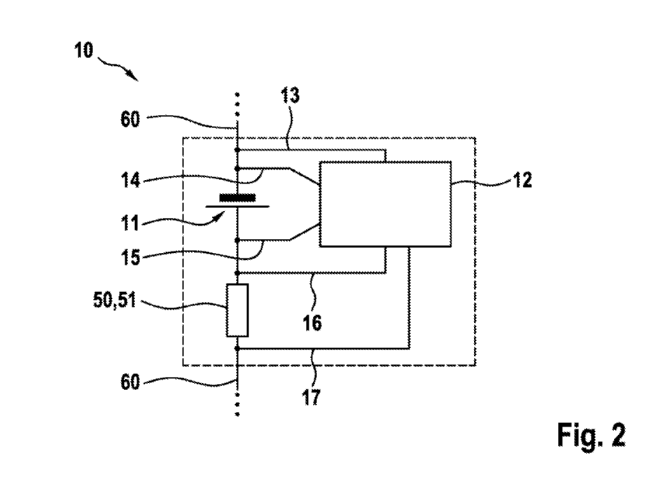

In this connection, FIG. 2 shows one embodiment of a battery cell 10 used in a battery module 1 according to FIG. 1 in greater detail.

According to the arrangement illustrated in FIG. 2, the cell voltage is able to be tapped off as voltage generated by the electrochemical unit 11, for example via the measurement lines 14 and 15.

At the same time or immediately temporally adjacent thereto, for example within the timeframe of a few microseconds, the voltage drop across the internal cell measurement resistor 50 is able to be determined via the measurement lines 16 and 17. According to the invention, in this case, the internal cell measurement resistor 50 is formed by an inherent or internal cell component 51 of the battery cell 10, for example by a cell terminal, also called terminal, a cell connector or the like.

Using this procedure, the need to provide an additional measurement resistor becomes obsolete; only components that are present in the cell 10 in any case are used. This simplifies construction, manufacture and handling of the battery cell 10 and of the battery module 1 as a whole, in particular in connection with a current-voltage measurement specific to one cell.

What is essential in specific embodiments of the measurement method according to the invention is the calibration of the current measurement and/or of the respective internal cell measurement resistors 50 in the individual battery cells 10, in particular using a precision measurement resistor 40 external to the cell with respect to the individual battery cells 10, the voltage drop across which precision measurement resistor is tapped off by way of the current monitoring device 30 via measurement lines 31 and 32.

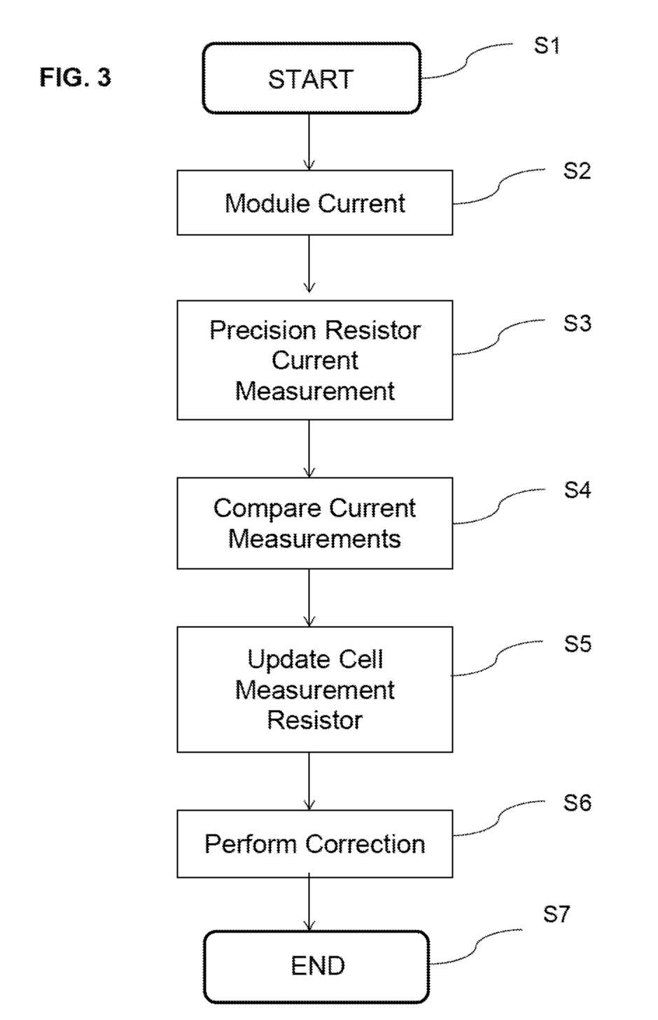

A corresponding calibration method that is able to be added to a measurement method according to the invention is illustrated in the form of a flow diagram in FIG. 3.

After a start phase S1, an electric current, which is constant over a defined time, is taken into account in a step S2. This is here in particular the module current flowing through all battery cells.

This may be performed either by setting a constant current or else by establishing and taking into account a phase with a constant current afterwards. Thus, for example, it may be established afterwards that a time interval—for example 10 ms—with a constant electric current occurs in a temporally variable profile of the electric current. This time interval with a constant current is then taken into account for the calibration.

In a following step S3, the current measurement value that was recorded at the precision measurement resistor 40 by the current monitoring device 30 via the measurement lines 31 and 32 is communicated to the individual cell monitoring devices 12 of the individual battery cells 10 via a superordinate monitoring device 20. This is performed for example via a bus 70.

In the following step S4, the current measurement of the individual battery cells 10 in connection with their cell monitoring devices 12 is compared with the communicated superordinate and precise measured current measurement value in connection with the precision measurement resistor 40.

In a following step S5, the cell measurement resistor 50 may be updated for example in a lookup table of the individual battery cells 10 in the respective cell monitoring device 12.

In a further step S6, there may then possibly be correction of the current measurement value measured in the respective battery cell 10, which was performed from the measurement of the voltage drop across the cell measurement resistor 50.

The start phase S1 and the end phase S7 embed the calibration method in a superordinate operating method.

These and other features and properties of the present invention are clarified further on the basis of the following explanations.

To determine the internal resistance of an electrical energy store 1, which may also be called battery module 1, or of the storage cells 10 of such a battery module 1, which are also called battery cells 10, the individual cell voltages of the battery cells are measured.

The required current measurement is performed across a precision measurement resistor 40 or shunt in the string 60, for example in connection with a superordinate monitoring device 20.

By dividing the individual cell voltages by the current, it is possible to calculate the internal resistance of each individual battery cell. Knowledge of the internal resistance is necessary to determine the state of aging of the individual battery cells 10, and makes it possible to output a power forecast. This may be indispensable for operational management.

As the current may change quickly during operation, a short latency time—for example of 1 to 10 μs—between cell voltage measurement and the current measurement is necessary. Otherwise, it is not possible to determine the resistance with sufficient accuracy.

This requirement in terms of the latency time is conventionally difficult to comply with and increases the complexity of implementation. The aim of the invention is to reduce this complexity.

To this end, according to the invention, in addition to the voltage measurement, the current measurement also takes place directly in the battery cell, in particular through the construction of what is called a smart cell.

A smart cell may be considered to be an energy storage cell that, in addition to the function of providing energy, also provides one or more functions for monitoring and/or diagnostics. Accordingly, such a cell, in addition to power and/or energy terminals, may also have a data interface.

According to the invention, on account of the spatial closeness of the sites of measurement, improved synchronization of current and voltage measurement is thus able to be ensured.

On account of the high costs of precision measurement resistors 40 or shunts, in this case, in the individual battery cells 10, pre-existing conductive components and paths—for example connections, terminals, cell connectors—in the battery cell 10 are used, these then functioning as the cell measurement resistor 50.

This is then advantageously calibrated via a precision measurement resistor 40 or shunt in the string 60 in the superordinate device, for example in a vehicle.

In this case, a current is set so as to be constant over time and then communicated to the individual battery cells 10 and in particular their cell monitoring devices 12, that is to say the smart cells, in the string 60.

This procedure may be performed for example during charging.

The individual battery cells 10 and in particular their cell monitoring devices 12, that is to say the smart cells, in the string 60 may then correct the determined current value and update the new value of the internal cell measurement resistor 50 or shunt in a lookup table.

This application is also contemplated without a configuration as a smart cell, that is to say without a refinement of a cell monitoring device 12. In this case, a current measurement may be performed on the plane of the battery module 1, for example at the module connectors. This would allow use of the existing architecture and maintain the advantages of short latency times.

According to the invention, the following advantages are achieved:
The determination of the internal cell resistance is greatly improved.
The requirements in terms of latency time between current measurement in the string 60 and voltage measurement in the battery cells 10 are able to be reduced.
Due to the improved determination of the internal resistance, it is possible to give a more accurate power forecast and information regarding the state of aging.
There would be cost savings through the reduction in the requirements in terms of apparatus, for example with regard to the provision of a plurality of precision measurement resistors and/or a reduction in the requirements in terms of latency time and thus in terms of communication.
The functionality of battery modules is improved through more accurate power prediction and age determination.

### LIST OF REFERENCE SIGNS

1 battery module
10 battery cell
11 electrochemical unit
12 cell monitoring device
13 measurement line
14 measurement line
15 measurement line
16 measurement line
17 measurement line
20 monitoring device
30 current monitoring device
31 measurement line
32 measurement line
40 precision measurement resistor
50 cell measurement resistor
51 internal cell component
60 string
70 bus

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. A method for determining an internal resistance of battery cells of a battery module, the method comprising the steps of:
determining a cell voltage of a battery cell as a voltage of a respective electrochemical unit of the battery cell;
determining a cell current of a battery cell from a voltage drop across a cell measurement resistor of the battery cell, wherein
an ohmic resistance of a component of the battery cell in a conductive path is used the cell measurement resistor.

2. The method as claimed in claim 1, wherein
a cell terminal, a feed line or an outlet line to or from a cell terminal and/or a cell connector for connecting adjacent battery cells in a battery module are used as the component in the conductive path of the battery cell.

3. The method as claimed in claim 1, wherein
the cell voltage and the cell current of a respective battery cell are measured within a latency time interval of 10 is.

4. The method as claimed in claim 1, wherein
the cell voltage and the cell current of a respective battery cell are measured at the same time.

5. The method as claimed in claim 1, wherein
the cell measurement resistor of a respective battery cell is calibrated using a precision measurement resistor external to the battery cell through a comparative measurement of a flow of electric current.

6. The method as claimed in claim 5, wherein
the cell measurement resistors of the respective battery cells are calibrated using the same precision measurement resistor that is external to the battery cell with respect to all battery cells.

7. The method as claimed in claim 5, wherein
the cell measurement resistor of a respective battery cell is calibrated for a time interval with a constant flow of current over at least 10 ms.

8. The method as claimed in claim 7, wherein
the constant flow of current for calibrating cell measurement resistors:
(i) is set by explicitly choosing operating conditions of a battery module underlying the battery cells, and/or
(ii) is established during operation and afterwards by monitoring a flow of current.

9. The method as claimed in claim 5, wherein
a current measurement value of a respective battery cell, acquired from comparative measurement of a flow of electric current for calibration purposes, is communicated to all battery cells of an underlying battery module and/or to a cell monitoring device formed in a respective battery cell.

10. The method as claimed in claim 5, wherein
a result of the calibration of a cell measurement resistor is stored and/or updated in a lookup table in the respective battery cell and/or in a cell monitoring device formed in a respective battery cell.

11. A battery module for a vehicle, comprising:
a plurality of battery cells that are connected to one another via a conductive path;
a monitoring device;
a precision resistor external to the plurality of battery cells in the conductive path; and
a cell monitoring device in each of the plurality of battery cells, wherein
in the battery module, a cell voltage of a respective battery cell is determined as a voltage of a respective electrochemical unit of the battery cell,
a cell current of the battery cell is determined from a voltage drop across a cell measurement resistor of the battery cell, wherein an ohmic resistance of a component of the battery cell in the conductive path is used as the cell measurement resistor.

12. A vehicle, comprising:
a battery module as claimed in claim 11; and
a load that is connectable to the battery module in order to be supplied with energy from the battery module.
